(19) United States
(12) Patent Application Publication
(10) Pub. No.: US 2026/0003041 A1
(43) Pub. Date: Jan. 1, 2026

(54) LIGHTING DEVICE, RANGING DEVICE, AND ONBOARD DEVICE

(71) Applicant: SONY SEMICONDUCTOR SOLUTIONS CORPORATION, KANAGAWA (JP)

(72) Inventors: MIDORI KANAYA, KANAGAWA (JP); TAKASHI KOBAYASHI, KANAGAWA (JP)

(21) Appl. No.: 18/880,652

(22) PCT Filed: Jun. 23, 2023
(86) PCT No.: PCT/JP2023/023277

§ 371 Date: Jan. 2, 2025

(30) Foreign Application Priority Data
Jul. 26, 2022 (JP) 2022-118834

(51) Int. Cl. G01S 7/481; G01S 17/08; G02B 5/30; H01S 5/065

(52) U.S. Cl. CPC G01S 7/4815; G01S 17/08; G02B 5/3016; H01S 5/0657

(57) ABSTRACT

For example, a lighting device capable of FOV switching is provided.

The lighting device change a projection range of first light and a projection range of second light by causing a light-emitting unit and an optical member disposed on the optical path of the first light and the second light to act differently on the first light and the second light, the light-emitting unit including a first light-emitting element that emits the first light and a second light-emitting element that emits the second light.

### TECHNICAL FIELD

The present disclosure relates to a lighting device, a ranging device, and an onboard device.

### BACKGROUND ART

Lighting devices have been developed to be used for applications such as distance measurement and object shape recognition according to measurement of the spatial propagation time of light (ToF: Time of Flight) and to be applied to an LiDAR (Laser Imaging Detection And Ranging) method essential for automated driving systems of vehicles. As a method for measurement using the ToF method, light emitted from a plurality of light-emitting elements is diffused by a diffuser panel and is uniformly emitted over the range of measurement (uniform irradiation), and then the reflected light is detected by a photodetector including two-dimensionally separated light receiving portions. Furthermore, as a method for increasing a distance of measurement, light emitted from a plurality of light-emitting elements is projected nearly in parallel through a collimator lens, and then spot light beams are projected (spot irradiation) to an object to be measured. For example, in PTL 1 below, a ranging device including two light sources (for uniform irradiation and spot irradiation) is described.

### CITATION LIST

### Patent Literature

### PTL 1

U.S. Patent Application Publication No. 2019/0137856 (Specification)

### SUMMARY

### Technical Problem

A distance-measurement range, that is, a viewing angle corresponding to the irradiation range of a laser beam is called an FOV (Field of view) and is set according to the purpose of use of a device. For example, a device intended for an onboard LiDAR is required to be able to measure short distances, that is, to have a large FOV (wide FOV) for purposes such as peripheral surveillance, whereas the device is required to be able to measure long distances, that is, to have a small FOV (narrow FOV) during high-speed driving or the like. The technique described in PTL 1 requires devices having different FOVs, which may lead to upsizing of the overall device and an increase in cost.

An object of the present disclosure is to provide a lighting device capable of switching different FOVs, and a ranging device and an onboard device that include the lighting device.

### Solution to Problem

The present disclosure is, for example, a lighting device including:
a light-emitting unit including a first light-emitting element that emits first light and a second light-emitting element that emits second light,
wherein the projection range of the first light and the projection range of the second light are changed by causing the light-emitting unit and an optical member disposed on the optical path of the first light and the second light to act differently on the first light and the second light.

The present disclosure is, for example, a ranging device including:
the lighting device;
a control unit that controls the lighting device;
a light receiving unit that receives reflected light from an object; and
a ranging unit that calculates a measured distance from image data obtained by the light receiving unit.

The present disclosure may be an onboard device including the foregoing ranging device.

### BRIEF DESCRIPTION OF DRAWINGS

FIG. 1 is a block diagram illustrating a configuration example of a ranging device according to an embodiment.

FIGS. 2A and 2B are explanatory drawings of a specific example of a ranging method.

FIG. 3 is an explanatory drawing of a configuration example of a light-emitting unit according to a first embodiment.

FIG. 4 is a schematic diagram of first light and second light.

FIG. 5 is an explanatory drawing illustrating an example of a first light-emitting element group and a second light-emitting element group.

FIG. 6 is an explanatory drawing illustrating an emission switching example of the first light-emitting element group and the second light-emitting element group.

FIG. 7 is an enlarged view of first light-emitting elements and second light-emitting elements.

FIGS. 8A and 8B are explanatory drawings of an FOV extended by a diffraction element according to the first embodiment.

FIG. 9 is an explanatory drawing illustrating a configuration example of the diffraction element according to the first embodiment.

FIGS. 10A and 10B are explanatory drawings illustrating a cross-sectional configuration example of the diffraction element according to the first embodiment.

FIGS. 11A and 11B are explanatory drawings illustrating a configuration example of an organic liquid crystal element according to a second embodiment.

FIGS. 12A and 12B are explanatory drawings illustrating a configuration example of a metamaterial according to a third embodiment.

FIG. 13 is an explanatory drawing illustrating a configuration example of a light-emitting unit according to a fourth embodiment.

FIG. 14 is an explanatory drawing illustrating the relationship among the light-emitting unit, a collimator lens, and an FOV.

FIG. 15 is an explanatory drawing illustrating a configuration example of a light-emitting unit according to a fifth embodiment.

FIG. 16 is an explanatory drawing illustrating a configuration example of a diffuser panel according to the fifth embodiment.

FIG. 17 is an explanatory drawing illustrating an example of the effect of the diffuser panel and a polarization diffraction element according to the fifth embodiment.

FIG. 18 is an explanatory drawing illustrating an example of the effect of the diffuser panel and the polarization diffraction element according to the fifth embodiment.

FIG. 19 is an explanatory drawing illustrating a configuration example of a light-emitting element according to a sixth embodiment.

FIGS. 20A and 20B are explanatory drawings illustrating a cross-sectional configuration example of a polarization control unit according to the sixth embodiment.

FIG. 21 illustrates a layout example of the polarization control unit according to the sixth embodiment.

FIG. 22 is an explanatory drawing illustrating a modification example of the sixth embodiment.

FIG. 23 is a block diagram illustrating a schematic configuration example of a vehicle control system.

FIG. 24 is an explanatory drawing illustrating an example of the installation positions of vehicle external information detectors and imaging units.

### DESCRIPTION OF EMBODIMENTS

Hereinafter, embodiments of the present disclosure will be described with reference to the drawings. The description will be made in the following order.

### First Embodiment

### Second Embodiment

### Third Embodiment

### Fourth Embodiment

### Fifth Embodiment

### Sixth Embodiment

### Modification Example

### Application Examples

The embodiments described below are preferred specific examples of the present disclosure, and the contents of the present disclosure are not limited to the embodiments. In the following description, constituent elements having substantially the same functional configurations are indicated by the same reference numerals, and a redundant description thereof is omitted as appropriate. In order to avoid a complicated illustration, only a part of the configuration may be denoted by reference numerals or the drawings may be simplified or scaled up/down.

### First Embodiment

### [Configuration of Ranging Device]

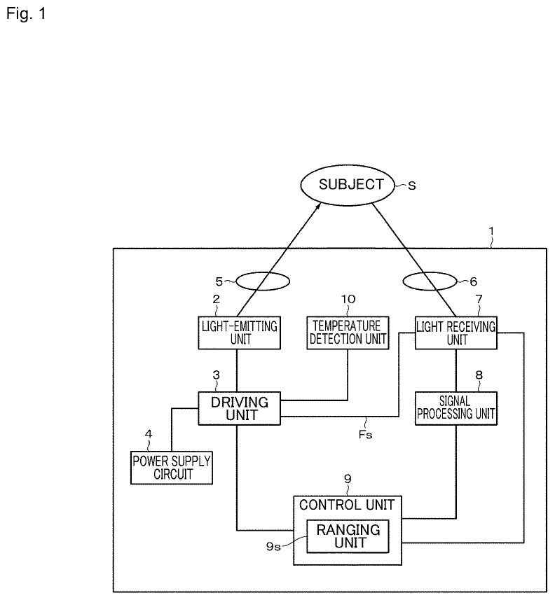

FIG. 1 shows a configuration example of a ranging device 1 as an embodiment of a lighting device according to the present technique. As illustrated in FIG. 1, the ranging device 1 includes a light-emitting unit 2, a driving unit 3, a power supply circuit 4, a light-emitting side optical system 5, a light receiving side optical system 6, a light receiving unit 7, a signal processing unit 8, a control unit 9, and a temperature detection unit 10.

The light-emitting unit 2 emits light using a plurality of light-emitting elements (light sources). As will be described later, as the light-emitting elements, the light-emitting unit 2 of the present example includes a plurality of light-emitting elements using VCSELs (Vertical Cavity Surface Emitting LASER) and is configured with the light-emitting elements arranged in a predetermined form, e.g., a matrix.

The driving unit 3 includes a power supply circuit 4 for driving the light-emitting unit 2. The power supply circuit 4 generates a power supply voltage of the driving unit 3 on the basis of, for example, an input voltage from a battery or the like, which is not illustrated, in the ranging device 1. The driving unit 3 drives the light-emitting unit 2 on the basis of the power supply voltage.

Light emitted from the light-emitting unit 2 is radiated on a subject S, which is a target of ranging, through the light-emitting side optical system 5. Furthermore, light that is light radiated in this way and reflected from the subject S enters the light receiving surface of the light receiving unit 7 through the light receiving side optical system 6.

The light receiving unit 7 is, for example, a light receiving element such as a CCD (Charge Coupled Device) sensor or a CMOS (Complementary Metal Oxide Semiconductor) sensor, and receives light that enters through the light receiving side optical system 6 as described above and is reflected from the subject S, converts the light into an electrical signal, and outputs the electrical signal. The light receiving unit 7 performs, for example, CDS (Correlated Double Sampling) processing and AGC (Automatic Gain Control) processing on the electrical signal obtained by photoelectric conversion of received light, and perform A/D (Analog/Digital) conversion processing. Furthermore, a signal as digital data is output to the signal processing unit 8 at a subsequent stage. Moreover, the light receiving unit 7 according to the present embodiment outputs a frame synchronizing signal Fs to the driving unit 3. Thus, the driving unit 3 can cause the light-emitting elements in the light-emitting unit 2 to emit light at a timing corresponding to the frame period of the light receiving unit 7.

The signal processing unit 8 is configured as a signal processor by, for example, a DSP (Digital Signal Processor). The signal processing unit 8 performs various kinds of signal processing on a digital signal input from the light receiving unit 7.

The control unit 9 is configured with a microcomputer including, for example, a CPU (Central Processing Unit), a ROM (Read Only Memory), and RAM (Random Access Memory) or is configured with an information processor such as a DSP. The control unit 9 controls the driving unit 3 to control a light-emitting operation performed by the light-emitting unit 2 and controls a light receiving operation performed by the light receiving unit 7.

The control unit 9 has the function of a ranging unit 9s. The ranging unit 9s measures a distance to a subject S on the basis of a signal (that is, a signal obtained by receiving light reflected from the subject S) input through the signal processing unit 8. The ranging unit 9s of the present example measures a distance to each part of the subject S to identify the three-dimensional shape of the subject S. A specific ranging method of the ranging device 1 will be described later.

The temperature detection unit 10 detects the temperature of the light-emitting unit 2. The temperature detection unit 10 can be configured to detect a temperature by using, for example, a diode. In the present example, information about the temperature detected by the temperature detection unit 10 is supplied to the driving unit 3, so that the driving unit 3 can drive the light-emitting unit 2 on the basis of the information about the temperature.

### [Ranging Method]

As a ranging method of the ranging device 1, for example, a ranging method using an STL (Structured Light) method or a ToF method can be adopted. The STL method is a method for measuring a distance on the basis of an image of the subject S irradiated with light having a predetermined bright/dark pattern, e.g., a dot pattern or a grid pattern.

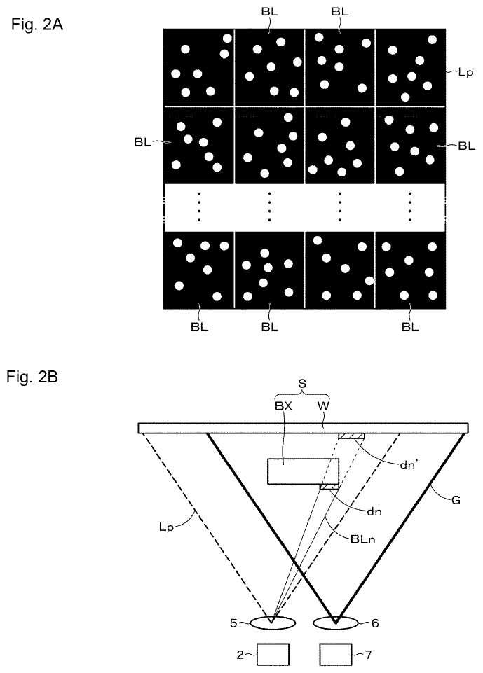

FIG. 2 is an explanatory drawing of the STL method. In the STL method, for example, pattern light Lp in a dot pattern illustrated in FIG. 2A is projected to the subject S. The pattern light Lp is divided into a plurality of blocks BL, and the blocks BL are allocated with different dot patterns (an overlap is avoided between the blocks BL).

FIG. 2B is an explanatory drawing of the ranging principle of the STL method. In this example, a wall W and a box BX disposed in front of the wall W serve as the subject S and the pattern light Lp is projected to the subject S. “G” in FIG. 2B schematically represents an angle of view of the light receiving unit 7. Furthermore, “BLn” in FIG. 2B means light of the certain block BL of the pattern light Lp. “dn” means a dot pattern of a block BLn shown in a received-light image obtained by the light receiving unit 7.

In the absence of the box BX in front of the wall W, the dot pattern of the block BLn in the received-light image is projected at the position of “dn” in the drawing. In other words, the position of the projected pattern of the block BLn in the received-light image changes, to be specific, the pattern deforms depending upon the presence or absence of the box BX.

In the STL method, the shape and depth of the subject S are determined by using deformation of a projected pattern, the deformation depending upon the object shape of the subject S. Specifically, in this method, the shape and depth of the subject S are determined by pattern deformation.

When the STL method is adopted, for example, an IR (Infrared) light receiving unit according to a global shutter method is used as the light receiving unit 7. Furthermore, in the case of the STL method, the ranging unit 9s controls the driving unit 3 such that the light-emitting unit 2 emits pattern light, detects pattern deformation of an image signal obtained via the signal processing unit 8, and calculates a distance on the basis of the pattern deformation.

The ToF method is a method for measuring a distance to an object by detecting a time of flight (time difference) of light that is emitted from the light-emitting unit 2 and is reflected by the object to reach the light receiving unit 7.

When a so-called direct ToF (dTOF) method is adopted as the ToF method, the light receiving unit 7 uses an SPAD (Single Photon Avalanche Diode) and the light-emitting unit 2 performs pulse driving. In this case, the ranging unit 9s calculates a time difference from emission to reception of light that is emitted from the light-emitting unit 2 and is received by the light receiving unit 7, on the basis of a signal input through the signal processing unit 8, and calculates a distance to each part of the subject S on the basis of the time difference and the speed of light.

When a so-called indirect ToF (iTOF) method (phase difference method) is adopted as the ToF method, for example, a light receiving unit capable of receiving IR is used as the light receiving unit 7.

### [Configuration Example of Light-emitting Unit]

### Example of Overall Configuration

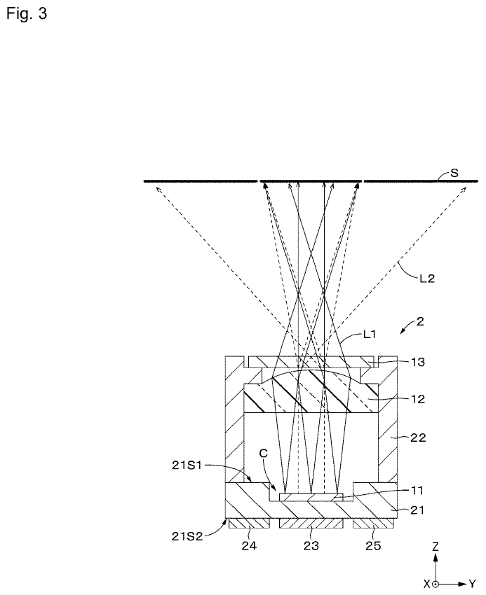

The light-emitting unit 2 according to the present embodiment will be described below. FIG. 3 is an explanatory drawing of an overall configuration example of the light-emitting unit 2. As illustrated in FIG. 3, the light-emitting unit 2 includes, for example, a collimator lens 12 and a diffraction element 13 (an example of an optical member according to the present embodiment). Furthermore, the light-emitting unit 2 includes a plurality of light-emitting elements 11. Specifically, the light-emitting unit 2 includes a plurality of first light-emitting elements 11A and a plurality of second light-emitting elements 11B. The first light-emitting elements 11A emit first light L1. The second light-emitting elements 11B emit second light L2. The first light L1 and the second light L2 have different polarization characteristics. For example, the first light L1 is TM (Transverse Magnetic wave) polarized light while the second light L2 is TE (Transverse Electric wave) polarized light, so that the polarization characteristics are obtained with polarization directions orthogonal to each other. The first light L1 may be TE polarized light, and the second light L2 may be TM polarized light. When the first light-emitting elements 11A and the second light-emitting elements 11B do not need to be distinguished from each other or when the individual light-emitting elements do not need to be distinguished from one another, the light-emitting elements may be collectively referred to as the light-emitting elements 11.

For example, the collimator lens 12 and the diffraction element 13 are placed in this order on the optical path of light emitted from the light-emitting element 11 (the first light L1 and the second light L2). The light-emitting element 11 is held by, for example, a holding part 21, and the collimator lens 12 and the diffraction element 13 are held by, for example, a holding part 22. For example, the holding part 21 has one anode electrode portion 23 and two cathode electrode portions 24 and 25, for example, on a surface 2152 opposite to a surface 2151 holding the light-emitting element 11.

The first light-emitting element 11A and the second light-emitting element 11B are, for example, surface-emitting semiconductor lasers of surface emission type. The first light-emitting elements 11A and the second light-emitting elements 11B are electrically separated from each other. In the present embodiment, the anode electrode portion 23 is connected as a common configuration to each of the light-emitting elements. Moreover, among the two cathode electrode portions 24 and 25, for example, the cathode electrode portion 24 is connected to the first light-emitting element 11A while the cathode electrode portion 25 is connected to the second light-emitting element 11B. As a matter of course, unlike in the connection of the present example, a cathode electrode portion may be connected as a common configuration to each of the light-emitting elements while different anode electrode portions may be connected to the first light-emitting element 11A and the second light-emitting element 11B, respectively.

The collimator lens 12 emits the first light L1 emitted from the first light-emitting elements 11A and the second light L2 emitted from the second light-emitting elements 11B, as nearly parallel rays. For example, the collimator lens 12 is a lens for collimating each of the first light L1 and the second light L2 and couples the collimated light to the diffraction element 13. The first light L1 and the second light L2 as nearly parallel rays are projected like spot light beams to the subject S.

The diffraction element 13 is a polarization diffraction element (DOE) for dividing a light beam having passed through the collimator lens 12 into 3×3 beams. Light pencils emitted from the first light-emitting elements 11A and the second light-emitting elements 11B are subjected to tiling by the diffraction element 13. The diffraction element 13 acts only on light (e.g., the second light L2) having one of the polarization characteristics, so that the number of light beam spots of the second light L2 can be increased to extend the projection range (irradiation range).

The holding part 21 and the holding part 22 are provided to hold the light-emitting element 11, the collimator lens 12, and the diffraction element 13. Specifically, the holding part 21 holds the light-emitting element 11 in a recess portion C provided on the top surface (surface 21S1). The holding part 22 holds the collimator lens 12 and the diffraction element 13. The collimator lens 12 and the diffraction element 13 are held by the holding part 22 with, for example, adhesive.

A plurality of electrode portions are provided on the back side (surface 21S2) of the holding part 21. Specifically, provided on the surface 21S2 of the holding part 21 are the anode electrode portion 23 shared by the first light-emitting elements 11A and the second light-emitting elements 11B, the cathode electrode portion 24 connected to the first light-emitting elements 11A, and the cathode electrode portion 25 connected to the second light-emitting elements 11B.

Alternatively, the collimator lens 12 and the diffraction element 13 may be held by the holding part 21 instead of the holding part 22.

### (Specific Example of Light-Emitting Element)

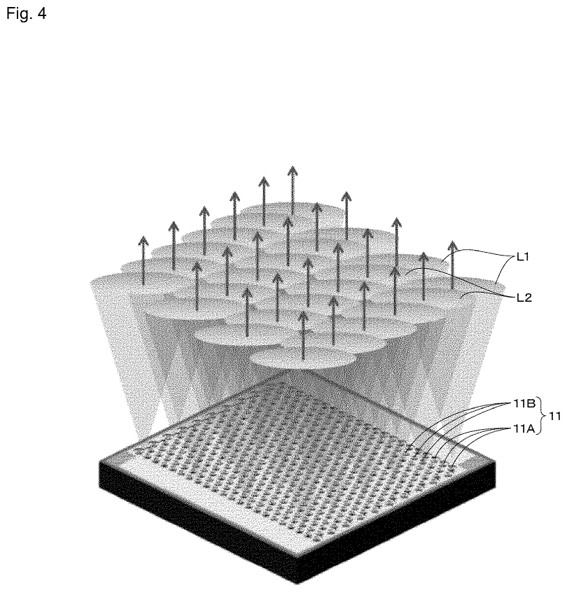

A specific example of the light-emitting element 11 will be described below. As described above, the light-emitting element 11 includes the first light-emitting element 11A and the second light-emitting element 11B. For example, the light-emitting elements measure approximately 1 cm per side, and the nearly three hundreds to six hundreds light-emitting elements 11 are placed. The light-emitting elements have an optical output of about 1 W to 5 W. As a matter of course, these numeric values are merely exemplary and the light-emitting elements are not limited to the indicated numeric values. As schematically shown in FIG. 4, the first light L1 is emitted from the first light-emitting elements 11A and the second light L2 is emitted from the second light-emitting elements 11B.

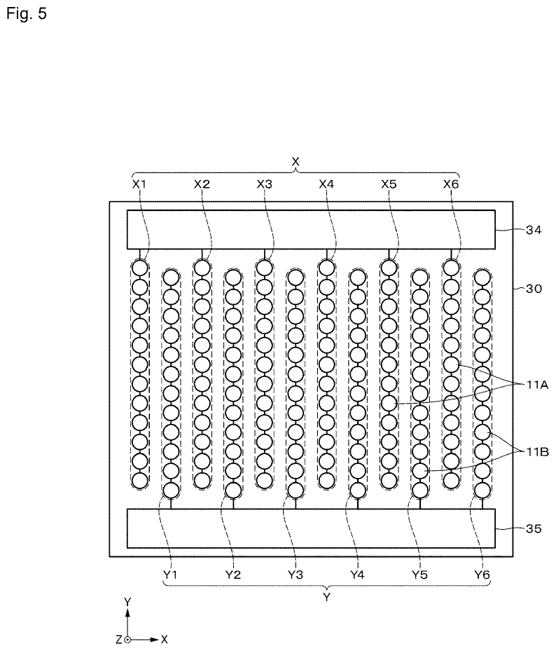

For example, as shown in FIG. 5, the first light-emitting elements 11A constitute a plurality of (e.g., six in FIG. 5) first light-emitting unit groups X (first light-emitting element groups X1 to X6), each including the n (e.g., 12 in FIG. 5) first light-emitting elements 11A extending in one direction (for example, the Y-axis direction). Likewise, the second light-emitting elements 11B constitute a plurality of (e.g., six in FIG. 5) second light-emitting unit groups Y (second light-emitting element groups Y1 to Y6), each including the m (e.g., twelve in FIG. 5) second light-emitting elements 11B extending in one direction (for example, the Y-axis direction).

For example, as shown in FIG. 5, the first light-emitting element groups X1 to X6 and the second light-emitting element groups Y1 to Y6 are alternately placed on an n-type substrate 30 having a rectangular shape. The first light-emitting element groups X1 to X6 are electrically connected to, for example, an electrode pad 34 provided along one side of the n-type substrate 30, and the second light-emitting element groups Y1 to Y6 are electrically connected to, for example, an electrode pad 35 provided on the other side opposite to the one side of the n-type substrate 30. In the example of FIG. 5, the first light-emitting element groups X1 to X6 and the second light-emitting element groups Y1 to Y6 are alternately placed. The configuration is not limited thereto. For example, the number of first light-emitting elements 11A and the number of second light-emitting elements 11B can be arranged in any matrix according to the number of desired light spots, the positions of the light spots, and the amount of light output. For example, one row of the second light-emitting elements 11B may be placed for every two rows of the first light-emitting elements 11A. Although the first light-emitting elements 11A and the second light-emitting elements 11B are equal in number in the present embodiment, the number of first light-emitting elements 11A may be different from the number of second light-emitting elements 11B. Moreover, the first light-emitting elements 11A and the second light-emitting elements 11B may have different FFPs (Far Field Patterns).

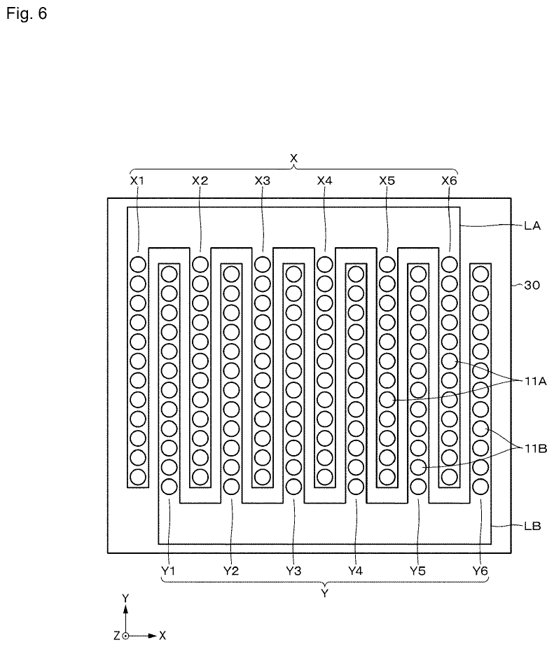

By switching the current flowing to the electrode pad, the desired light-emitting element is controlled to emit light. For example, as shown in FIG. 6, the first light-emitting elements 11A (the first light-emitting elements 11A surrounded by a line LA) included in the first light-emitting element groups X1 to X6 can be caused to emit light by passing current through the electrode pad 34. Furthermore, the second light-emitting elements 11B (the second light-emitting elements 11B surrounded by a line LB) included in the second light-emitting element groups Y1 to Y6 can be caused to emit light by passing current through the electrode pad 35.

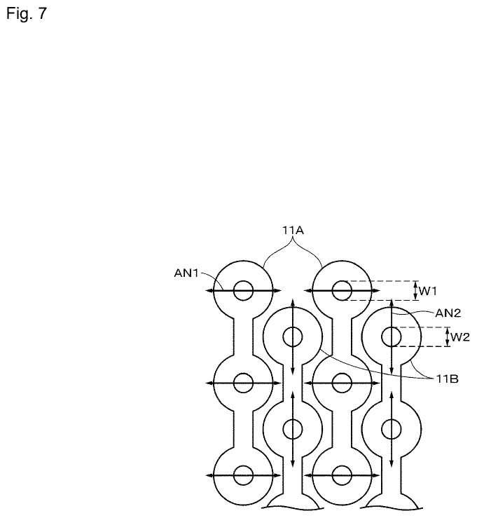

FIG. 7 is an enlarged view of a part of the matrix of the first light-emitting elements 11A and the second light-emitting elements 11B in FIGS. 5 and 6. The first light-emitting element 11A has a light emission area with (OA diameter W1) while the second light-emitting element 11B has a light emission area with (OA diameter W2). The light-emitting elements may have equal or different light emission areas. An arrow AN1 of the first light-emitting element 11A and an arrow AN2 of the second light-emitting element 11B in FIG. 7 indicate the directions of polarization. As described above, the direction of polarization of the first light-emitting element 11A and the direction of polarization of the second light-emitting element 11B are orthogonal to each other. For example, by adjusting the stress distribution of the first light-emitting elements 11A and the stress distribution of the second light-emitting elements 11B, polarization characteristics can be obtained with polarization directions orthogonal to each other. As a matter of course, the polarization characteristics are not limited thereto. As will be described later, desired polarization characteristics can be obtained using a polarization control member or the like.

### [Diffraction Element]

### (Effect)

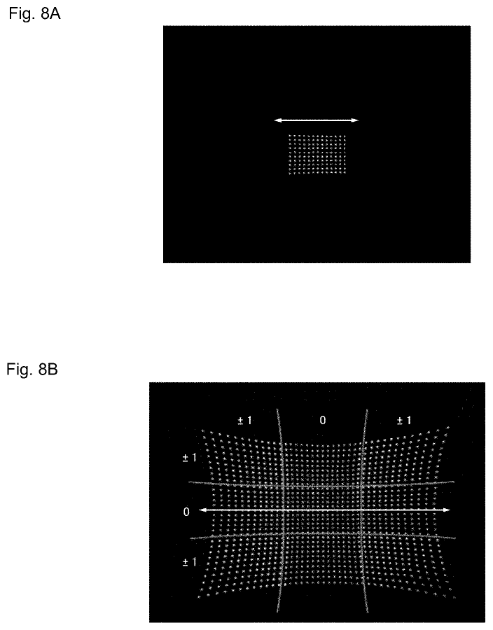

The diffraction element 13 will be described below. The diffraction element 13 acts differently on the first light L1 and the second light L2 that are emitted from the first light-emitting elements 11A. In the present embodiment, the diffraction element 13 does not act on the first light L1 but acts only on the second light L2. Specifically, the diffraction element 13 does not act on the first light L1 but only refracts or diffracts the second light L2. FIG. 8A shows an example of an irradiation pattern of the first light L1. FIG. 8B shows an example of an irradiation pattern of the second light L2. Since the diffraction element 13 does not act on the first light L1, the FOV does not extend but a high light density is obtained, enabling long-distance measurement.

As shown in FIG. 8B, the diffraction element 13 acts only on the second light L2, so that the FOV is three times wider than the FOV shown in FIG. 8A, in the horizontal and vertical directions. The range of expansion of the FOV varies depending on the structure of the diffraction element 13.

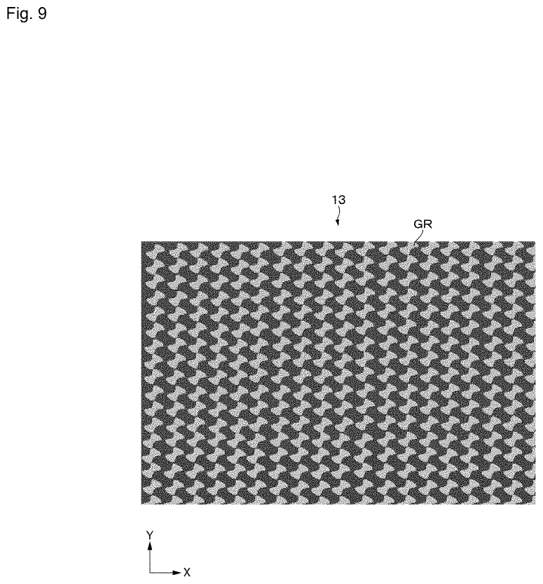

FIG. 9 is an enlarged view of the DOE pattern of the diffraction element 13. The diffraction element 13 has a grating structure GR that is a structure with a fine relief. The grating structure GR two-dimensionally formed in the present embodiment may be formed in a one-dimensional shape.

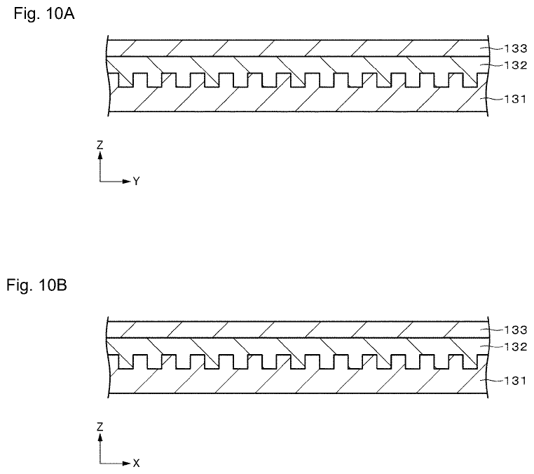

FIGS. 10A and 10B are cross-sectional views illustrating the sections of the diffraction element 13 according to the present embodiment. As illustrated in the drawings, for example, the diffraction element 13 has a three-layer structure in which a first layer 131, a second layer 132, and a third layer 133 are sequentially bonded in Z direction. The first layer 131 has a refractive index n1, and the third layer 133 has a refractive index n3. The refractive index of the second layer 132 varies depending on the direction and has a refractive index n2y in Y direction shown in FIG. 10A and a refractive index n2x in X direction shown in FIG. 10B. The diffraction element 13 having the three-layer structure that is a laminate of anisotropic materials. n1 and n2x are equal to each other (n1=n2x) while n1 and n2y are different from each other (n1≠n2y). The layers can be composed of any materials as long as the relationship between the refractive indexes is satisfied.

As described above, the diffraction element 13 have different refractive indexes in X direction and Y direction, so that the diffraction element 13 acts as a parallel plate for polarization in one direction (X direction) and acts as a diffraction element that refracts or diffracts a light beam for polarization in the direction (Y direction) orthogonal to one direction. In this way, the diffraction element 13 is a polarization diffraction element that refracts or diffracts, for example, the second light L2. The diffraction element 13 may be replaced with a three-dimensional hologram. Alternatively, the diffraction element 13 may be, for example, a Fresnel lens if the effect of refracting or diffracting light is obtained.

### [Operations of Ranging Device]

An operation example of the ranging device 1 will be described below. For example, when the ranging device 1 is applied to an onboard LiDAR, long-distance measurement may be required as in driving on a highway. In this case, control is performed to emit light from the first light-emitting element groups X1 to X6. Such control is performed by, for example, the control unit 9. The diffraction element 13 does not act on the first light L1 emitted from the first light-emitting elements 11A. Hence, the first light L1 is not divided and thus spot irradiation is obtained with a high light density (see FIG. 8A), enabling long-distance measurement with high accuracy.

Moreover, wide-range measurement may be required instead of long-distance measurement as in urban or city driving. In this case, control is performed to emit light from the second light-emitting element groups Y1 to Y6. Such control is performed by, for example, the control unit 9. The diffraction element 13 acts on the second light L2 emitted from the second light-emitting elements 11B. Hence, the second light L2 passes through the diffraction element 13 to extend the FOV (see FIG. 8B), enabling short-distance and wide-range measurement.

As described above, in the present embodiment, the FOV can be actively switched. Moreover, the need for preparing devices with different FOVs can be eliminated, thereby minimizing upsizing and additional cost of the ranging device 1.

### Second Embodiment

A second embodiment will be described below. In the description of the second embodiment, the same reference numerals are given to the same or homogenous configurations as the above-described configurations and duplicate descriptions are omitted as appropriate. The matters described in the first embodiment can be applied to the second embodiment unless otherwise mentioned. The same applies to third and subsequent embodiments.

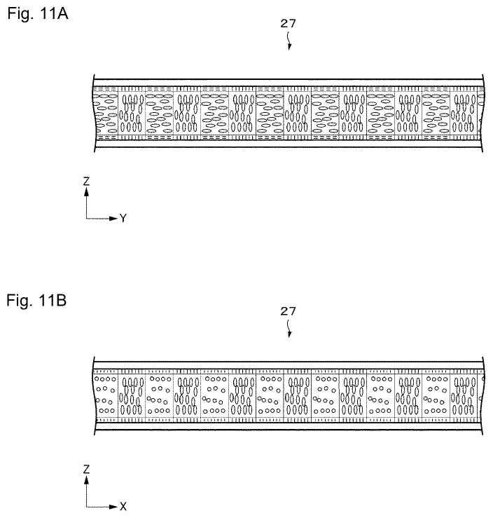

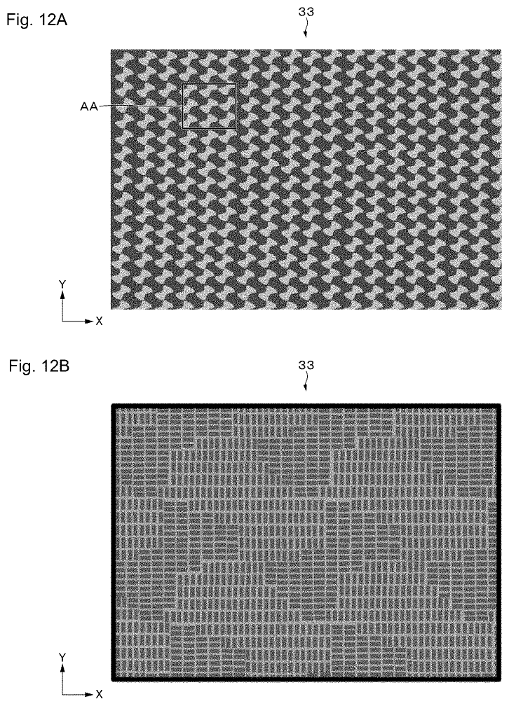

In the second embodiment, an optical member is a liquid crystal element, to be specific, an organic liquid crystal element 27 as a replacement for a diffraction element 13. FIGS. 11A and 11B are explanatory drawings illustrating a configuration example of the organic liquid crystal element 27. As illustrated in FIGS. 11A and 11B, the organic liquid crystal element 27 has different orientations in the X direction and Y direction. The direction of polarization of a light beam can be changed by switching light emission between a first light-emitting element 11A and a second light-emitting element 11B, thereby eliminating the need for switching the orientation of the organic liquid crystal element 27 to change the direction of polarization of the light beam. Thus, a circuit configuration or a flexible cable for switching the orientation of the organic liquid crystal element 27 is not necessary, and the switching time of the orientation of the organic liquid crystal element 27 does not cause any problems. The organic liquid crystal element 27 may be replaced with an inorganic liquid crystal element. An inorganic liquid crystal element is superior in temperature characteristics and heat resistance to an organic liquid crystal element and is usable for an application requiring high reliability, for example, installation in a vehicle.

Other effects of the second embodiment are basically similar to those according to the first embodiment. Specifically, the organic liquid crystal element 27 does not act on first light L1 but only acts on second light L2. Thus, spot irradiation is performed with a high light density without changing the FOV of the first light L1, whereas the second light L2 is projected to an object with the extended FOV. Thus, the same effect can be obtained as in the first embodiment.

### Third Embodiment

A third embodiment will be described below. In the third embodiment, an optical member is a metamaterial 33. FIG. 12A is a configuration example of the metamaterial. FIG. 12B is an enlarged view of a part indicated by reference character AA in FIG. 12A. The metamaterial 33 can generate different diffraction characteristics according to the direction of polarization.

Other effects of the third embodiment are basically similar to those according to the first embodiment. Specifically, the metamaterial 33 does not act on first light L1 but only acts on second light L2. Hence, spot irradiation is performed with a high light density without changing the FOV of the first light L1, whereas the second light L2 is projected to an object with the extended FOV. Thus, the same effect can be obtained as in the first embodiment.

### Fourth Embodiment

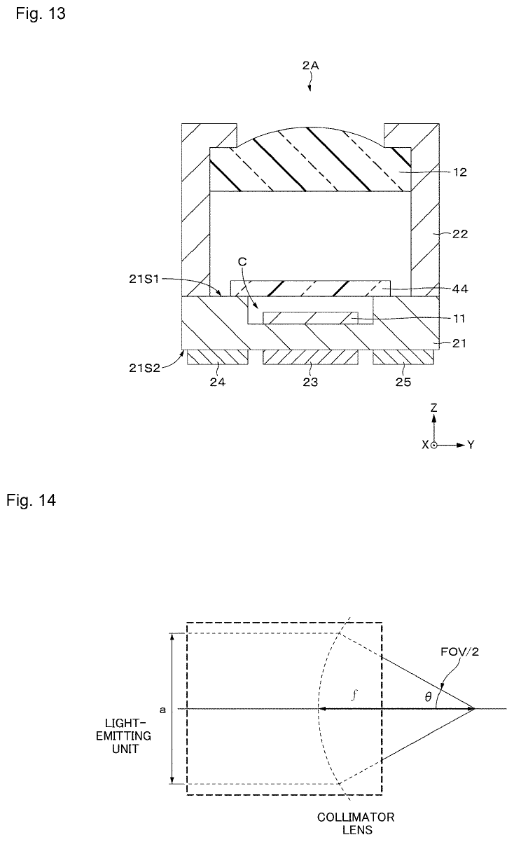

A fourth embodiment will be described below. In the fourth embodiment, the configuration of a light-emitting unit is different from that of the first embodiment. FIG. 13 illustrates a configuration example of the light-emitting unit (light-emitting unit 2A) according to the fourth embodiment. The light-emitting unit 2A is different from the light-emitting unit 2 in that a diffraction element 13 is absent and a polarization diffraction element 44 is provided as an optical member of the present embodiment. A light-emitting elements 11 (a first light-emitting element 11A and a second light-emitting element 11B), the polarization diffraction element 44, and a collimator lens 12 are placed in this order on the optical path of first light L1 and second light L2. The polarization diffraction element 44 is held by, for example, a holding part 21 but may be held by a holding part 22.

The polarization diffraction element 44 is, for example, a Fresnel lens that constitutes a lens pair with the collimator lens 12. This changes the focal distance of the collimator lens 12 to the combined focal distance of the focal distance of the collimator lens 12 and the polarization diffraction element 44, thereby changing the FOV. The polarization diffraction element 44 acts on only one of first light L1 and second light L2.

The present embodiment will be specifically described below. First, in the absence of the polarization diffraction element 44, that is, when only the collimator lens 12 is present as illustrated in FIG. 14, a projection optical axis that determines an FOV corresponding to an irradiation area has an inclination angle θ as expressed by formula 1 below. f in formula 1 is the focal distance (mm) of the collimator lens 12. a is a value obtained by multiplying Nx and Dx. Nx is the number of light-emitting elements 11 in the horizontal direction (X direction) of the light-emitting unit 2A, and Dx is the pitch (mm) of the light-emitting elements.

$$[ Math . 1 ]$$

$$θ = {Sin}^{- 1} \frac{a}{2 f}$$

The provision of the polarization diffraction element 44 changes f from the focal distance of the collimator lens 12 to the combined focal distance of the focal distance of the collimator lens 12 and the focal distance of the polarization diffraction element 44. According to the change of the focal distance, θ changes, that is, the FOV changes. Specifically, only the collimator lens 12 acts on the first light L1 while the collimator lens 12 and the polarization diffraction element 44 act on the second light L2, allowing a change of the FOV. The lens power of the polarization diffraction element 44 is made positive or negative, so that the FOV can be increased or reduced.

A specific example will be described below. A mechanical distance from the collimator lens 12 to a light spot (each light-emitting element) needs to be equal at a narrow FOV and a wide FOV. Thus, the polarization diffraction element 44 includes an element having negative lens power. Specific values are determined as follows:

$$Nx = 40 μm , Dx = 50 μm$$

Focal distance f1 of the collimator lens 12=2 mm
Focal distance f2 of polarization diffraction element 44=−2 mm

A distance between the collimator lens 12 and the polarization diffraction element 44 is 1 mm.

At this point, for example, the polarization diffraction element 44 does not act on the second light L2 and the FOV of the second light L2 is 60 deg, whereas the FOV of the first light L1 can be reduced to 29 deg, about a half of 60 deg when the polarization diffraction element 44 acts on the first light L1.

Furthermore, when the lens power of the polarization diffraction element 44 includes the positive power of an element, the polarization diffraction element 44 acts only on the second light L2, so that the FOV of the second light L2 can be increased. At this point, the polarization diffraction element 44 does not act on the first light L1, so that the FOV of the first light L1 is unchanged.

The polarization diffraction element 44 may be a liquid crystal element as described in the second embodiment or may be a polarized metamaterial. Alternatively, the polarization diffraction element 44 may be a plurality of microlenses. In this case, only the light-emitting elements that change the FOV and the microlenses may be placed to face each other. Thus, a configuration can be obtained such that the focal distance changes only for some of the light-emitting elements and the FOV changes.

In this case, the light-emitting unit may only include light-emitting elements having identical polarization characteristics.

### Fifth Embodiment

A fifth embodiment will be described below. The fifth embodiment is an application example in which first light L1 emitted from a first light-emitting element 11A and second light L2 emitted from a second light-emitting element 11B are diffused through a diffuser plate 51 and are uniformly projected (uniform projection) over the range of measurement. For the diffuser plate 51 having the function of determining the range of measurement (irradiation range), a polarization diffraction element 54 is further disposed to extend or narrow the range.

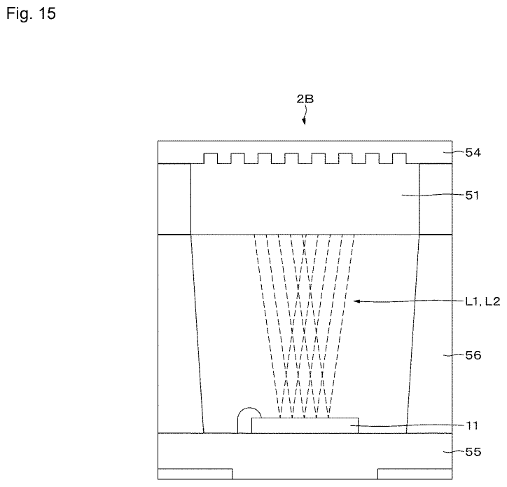

FIG. 15 illustrates a configuration example of a light-emitting unit 2B according to the present embodiment. The light-emitting unit 2B includes a light-emitting element 11, the diffuser plate 51, and the polarization diffraction element 54 that are placed in this order on the optical path of the first light L1 and the second light L2. The light-emitting element 11 is supported by a support part 55, and the diffuser plate 51 is supported by a support part 56. The edge of the polarization diffraction element 54 is supported by the top surface of the support part 56.

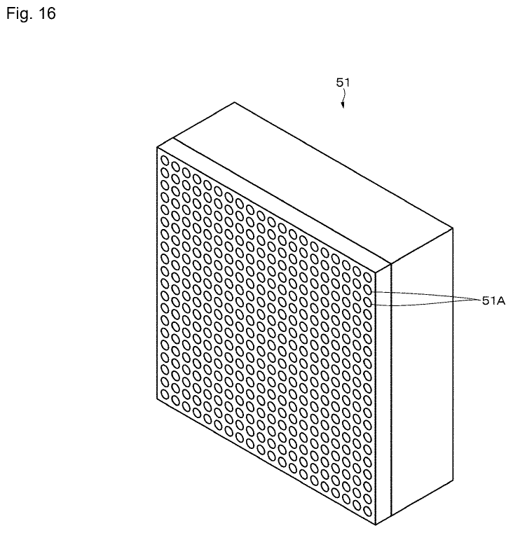

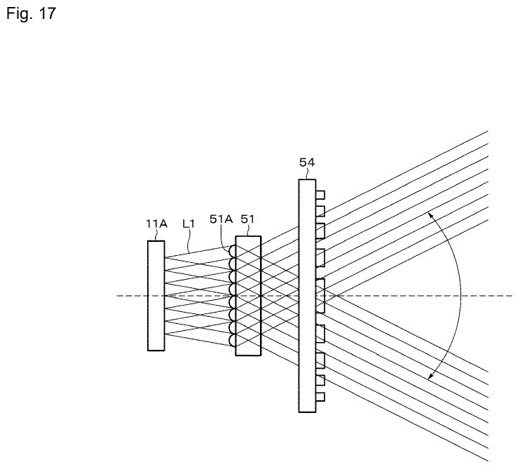

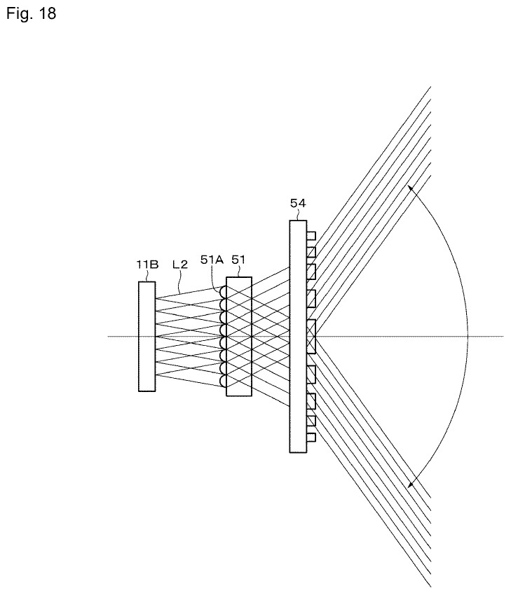

FIG. 16 is a perspective view illustrating an example of the diffuser plate 51. Examples of the diffuser plate 51 include a lens diffuser plate having an array of small lenses 51A. The diffuser plate 51 is typically an array of the small lenses 51A (several tens μm order) that have the function of diffusing the light of the light-emitting element 11 into a uniform brightness distribution. The lenses 51A are opposed to the light-emitting element 11. The diffuser plate 51 may be a plate using diffraction instead of a lens diffuser plate.

The polarization diffraction element 54 corresponding to an optical member in the present embodiment is, for example, an element having a grating structure GR. The polarization diffraction element 54 may be a liquid crystal element or a polarized material.

Referring to FIGS. 17 and 18, the effects of the diffuser plate 51 and the polarization diffraction element 54 will be described below. As shown in FIG. 17, the polarization diffraction element 54 does not act on the first light L1 emitted from the first light-emitting element 11A. In this case, the FOV is determined only by the effect of the diffuser plate 51. In contrast, the polarization diffraction element 54 acts on the second light L2 emitted from the second light-emitting element 11B. As shown in FIG. 18, the second light L2 is diffused through the diffuser plate 51 and then is further diffused by the effect of the polarization diffraction element 54. Thus, the FOV (indicated by a curved arrow) becomes larger than that of FIG. 17.

### Sixth Embodiment

A sixth embodiment will be described below. In the present embodiment, the configuration of a light-emitting element 11 is different from those of the foregoing embodiments. Specifically, a first light-emitting element 11A and a second light-emitting element 11B are composed of Q-switch lasers. Moreover, each of the light-emitting elements has an SRG (Surface Relief Grating) structure, so that polarization characteristics are controlled to be, for example, orthogonal to each other.

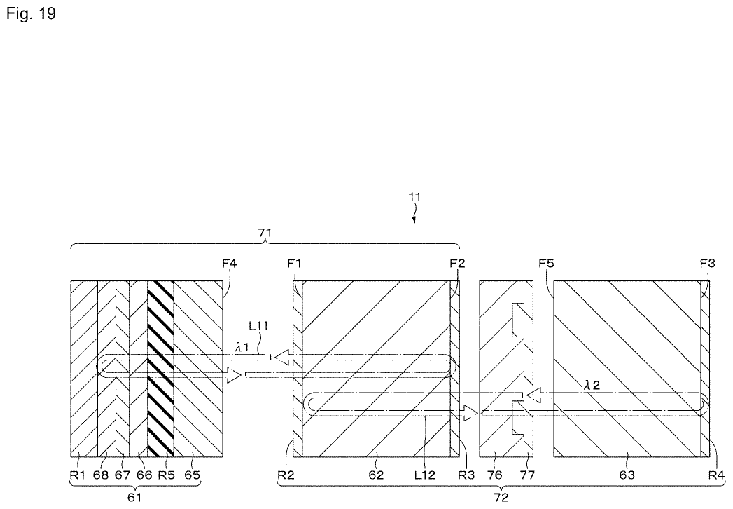

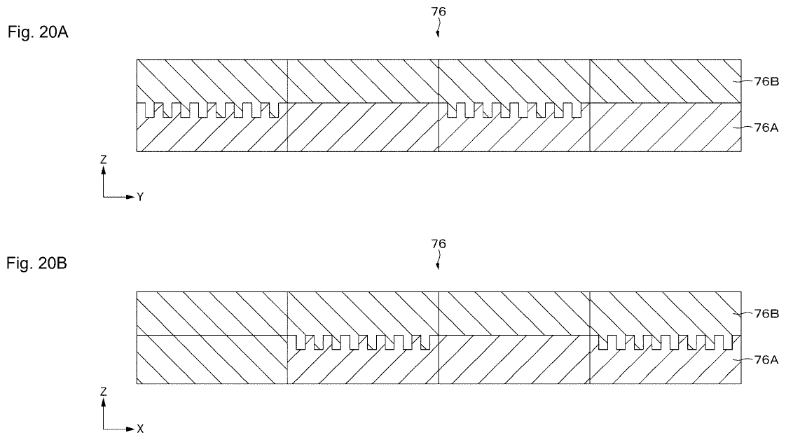

FIG. 19 illustrates a configuration example of the light-emitting element 11 according to the present embodiment. The light-emitting element 11 is configured such that an excitation light source layer 61, a solid-state laser medium 62, and a saturable absorber 63 are bonded together.

The excitation light source layer 61 is a surface emitting element and has a semiconductor layer having a laminated structure. The excitation light source layer 61 has a structure in which a substrate 65, a fifth reflective layer R5, a clad layer 66, an active layer 67, a clad layer 68, and a first reflective layer R1 are stacked in this order. The excitation light source layer 61 in FIG. 19 has a bottom-emission configuration in which excitation light of a continuous wave (CW) is emitted from the substrate 65. The excitation light source layer 61 may have a top-emission configuration in which CW excitation light is emitted from the first reflective layer R1.

The substrate 65 is, for example, an n-GaAs substrate. The substrate 65 absorbs a certain rate of light with a first wavelength 11 that is the excitation wavelength of the excitation light source layer 61, so that the substrate 65 desirably has a minimum thickness. On the other hand, the substrate 65 is desirably thick enough to keep mechanical strength during a bonding process, which will be described later.

The active layer 67 performs surface emission with the first wavelength λ1. The clad layer 68 is, for example, an AlGaAs clad layer. The first reflective layer R1 reflects light with the first wavelength λ1. The fifth reflective layer R5 has a fixed transmission for the light with the first wavelength λ1. For the first reflective layer R1 and the fifth reflective layer R5, for example, a semiconductor distribution reflective layer (DBR: Distributed Bragg Reflector) capable of electrical conduction is used. Current is injected from the outside through the first reflective layer R1 and the fifth reflective layer R5, recombination and light emission occur in a quantum well in the active layer 67, and then light with the first wavelength λ1 is emitted.

The fifth reflective layer R5 is disposed on, for example, the substrate 65. For example, the fifth reflective layer R5 includes a multilayer reflective film composed of Alz1Ga1-z1As/Alz2Ga1-z2As (0≤z1≤z2≤1) doped with an n-type dopant (e.g., silicon). The fifth reflective layer R5 is also referred to as n-DBR.

The active layer 67 includes a multiple quantum well layer formed by stacking, for example, an ANx1Iny1Ga1-x1-y1As layer and an Alx3Iny3Ga1-x3-y3As layer.

The first reflective layer R1 includes, for example, a multilayer reflective film composed of Alz3Ga1-z3As/AlZ4Ga1-z4As (0≤z3≤z4≤1) doped with a p-type dopant (e.g., carbon). The first reflective layer R1 is also referred to as p-DBR.

The semiconductor layers R5, 66, 67, 68, and R1 in a light source serving as an excitation light resonator can be formed using a crystal growth method such as the Metal Organic Chemical Vapor Deposition (MOCVD) method or the Molecular Beam Epitaxy (MBE) method. Furthermore, after crystal growth, driving can be performed through current injection after the process of mesa etching for element isolation, formation of an insulating film, and deposition of an electrode film.

The solid-state laser medium 62 is bonded on an end face of the substrate 65 of the excitation light source layer 61, opposite from the fifth reflective layer R5. Hereinafter, an end face of the solid-state laser medium 62 near the excitation light source layer 61 will be referred to as a first face F1, whereas an end face of the solid-state laser medium 62 near the saturable absorber 63 will be referred to as a second face F2. Furthermore, a laser-pulse emission face of the saturable absorber 63 will be referred to as a third face F3, and an end face of the excitation light source layer 61 near the solid-state laser medium 62 will be referred to as a fourth face F4. Moreover, an end face of the saturable absorber 63 near the solid-state laser medium 62 will be referred to as a fifth face F5. Although separated and illustrated for ease of convenience in FIG. 19, the fourth face F4 of the light-emitting element 11 is bonded to the first face F1 of the solid-state laser medium 62, and the second face F2 of the solid-state laser medium 62 is bonded to the fifth face F5 of the saturable absorber 63 with a polarization control unit 76 interposed therebetween. The polarization control unit 76 will be described later.

The light-emitting element 11 includes a first resonator 71 and a second resonator 72. The first resonator 71 resonates excitation light L11 with the first wavelength X1 between the first reflective layer R1 in the excitation light source layer 61 and a third reflective layer R3 in the solid-state laser medium 62. The second resonator 72 resonates emitted light L12 with a second wavelength X2 between a second reflective layer R2 in the solid-state laser medium 62 and a fourth reflective layer R4 in the saturable absorber 63.

The second resonator 72 is configured as a so-called Q-switch solid-state laser resonator. The third reflective layer R3, which is a highly reflective layer, is provided in the solid-state laser medium 62 such that the first resonator 71 can perform a stable resonating operation. In the case of an ordinary resonator, the third reflective layer R3 has the function of an output coupler and performs partial reflection for emitting light with the first wavelength X1. In contrast, in the first resonator 71 illustrated in FIG. 19, the third reflective layer R3 is used as a highly reflective layer to trap the power of the excitation light L11 with the first wavelength X1 in the first resonator 71.

As described above, in the first resonator 71 including the excitation light source layer 61 and the solid-state laser medium 62, three reflective layers (the first reflective layer R1, the fifth reflective layer R5, and the third reflective layer R3) are provided. Thus, the first resonator 71 has a coupled resonator (Coupled Cavity) structure.

By trapping the power of the excitation light L11 with the first wavelength X1 in the first resonator 71, the solid-state laser medium 62 is excited. Thus, Q-switch laser pulse oscillation occurs in the second resonator 72. The second resonator 72 resonates light with the second wavelength X2 between the second reflective layer R2 in the solid-state laser medium 62 and the fourth reflective layer R4 in the saturable absorber 63. While the second reflective layer R2 is a highly reflective layer, the fourth reflective layer R4 is a partially reflective layer having the function of an output coupler. In FIG. 19, the fourth reflective layer R4 is provided on one end face of the saturable absorber 63.

In this configuration, the polarization control unit 76 is provided between the solid-state laser medium 62 and the saturable absorber 63. The polarization control unit 76 has a flat relief grating structure GR on the optical path of the emitted light L12. The grating structure GR of the polarization control unit 76 is covered flat with a surface layer 77.

The solid-state laser medium 62 contains, for example, yttrium aluminum garnet (YAG) crystal Yb:YAG doped with ytterbium (Yb). In this case, the first wavelength X1 of the first resonator 15 is 940 nm, and the second wavelength X2 of the second resonator 72 is 1030 nm.

The solid-state laser medium 62 is not limited to Yb: YAG. For example, used as the solid-state laser medium 62 is at least one of Nd:YAG, Nd:YVO4, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and Yb:YAB. The solid-state laser medium 62 is not limited to crystal and may include ceramic materials.

Furthermore, the solid-state laser medium 62 may be the solid-state laser medium 62 of a four-level system or the solid-state laser medium 62 of a three-level system. Since each crystal has a different appropriate excitation wavelength (first wavelength λ1), a semiconductor material in the excitation light source layer 61 needs to be selected according to the material of the solid-state laser medium 62.

The saturable absorber 63 contains, for example, YAG (Cr:YAG) crystal doped with Cr (chrome). The saturable absorber 63 is a material that increases in transmittance when the intensity of incident light exceeds a predetermined threshold value. The excitation light L11 with the first wavelength λ1 from the first resonator 71 increases the transmittance of the saturable absorber 63 and leads to laser pulse emission with the second wavelength λ2. This is referred to as a Q-switch. As the material of the saturable absorber 63, V:YAG is also usable. Other types of the saturable absorber 63 may be used instead. Furthermore, an active Q-switch element may be used as the Q-switch.

FIG. 19 illustrates the excitation light source layer 61, the solid-state laser medium 62, the polarization control unit 76, and the saturable absorber 63 as separate parts that constitute a laminated structure integrated by bonding through a bonding process. As an example of the bonding process, room-temperature bonding, atomic diffusion bonding, or plasma activation bonding can be used. Alternatively, other bonding (joining) processes can be used.

Stable bonding of the solid-state laser medium 62 to the excitation light source layer 61 requires flattening of a surface of the n-GaAs substrate 65 in the excitation light source layer 61. Hence, as described above, electrodes for injecting current to the first reflective layer R1 and the fifth reflective layer R5 are desirably disposed without being exposed from at least the surface of the substrate 65.

As described above, the light-emitting element 11 has a laminated structure, so that the produced laminated structure is easily divided into multiple chips by dicing or a laser array is easily formed such that the light-emitting elements 11 are placed in an array on one substrate.

When the light-emitting element 11 having a laminated structure is produced in the bonding process, surface roughness Ra of each layer needs to be set at about 1 nm or less. Moreover, in order to avoid an optical loss of an interface between layers, a dielectric multilayer film may be disposed between the layers to bond the layers together. For example, the substrate 65 serving as the base substrate of the light-emitting element 11 has a refractive index n of 3.2, which is higher than that of YAG (n:1.8) or an ordinary dielectric multilayer film material. Thus, when the solid-state laser medium 62 and the saturable absorber 63 are bonded to the excitation light source layer 61, an optical loss caused by a mismatch between refractive indexes needs to be prevented. Specifically, an anti-reflection film (AR coating film or a nonreflective coating film) that does not reflect light with the first wavelength X1 from the first resonator 71 is desirably disposed between the excitation light source layer 61 and the solid-state laser medium 62. Moreover, an anti-reflection film (AR coating film or a nonreflective coating film) is also desirably disposed between the solid-state laser medium 62 and the saturable absorber 18.

Some bonding materials are hard to polishing. For example, a material such as SiO2 that is transparent at the first wavelength λ1 and the second wavelength λ2 may be formed into an underlayer for bonding, and the SiO2 layer may be polished to a surface roughness Ra of about 1 nm and used as an interface for bonding. In this case, materials other than SiO2 can be used for the underlayer, and the underlayer is not limited to the materials.

The dielectric multilayer film includes a short wave pass filter film (SWPF), a long wave pass filter film (LWPF), a band pass filter film (BPF), and an anti-reflection protective film (AR) protective film. Different kinds of dielectric multilayer film are desirably disposed as necessary. As a method for forming the dielectric multilayer film, physical vapor deposition (PVD) can be used. Specifically, deposition methods such as vacuum deposition, ion assisted deposition, and sputtering can be used. Any one of the deposition methods may be used. Furthermore, the characteristics of the dielectric multilayer film can also be selected as appropriate. For example, the second reflective layer R2 may be a short wave pass filter film, and the third reflective layer R3 may be a long wave pass filter film.

According to the present embodiment, the polarization control unit 76 that controls the ratio of TM polarized light and TE polarized light orthogonal to each other is provided in the second resonator 72. The grating structure GR may be formed on a surface of the solid-state laser medium 62.

FIGS. 20A and 20B illustrate a cross-sectional configuration example of the polarization control unit 76. For example, the polarization control unit 76 has a two-layer structure in which a first layer 76A and a second layer 76B are sequentially bonded in the Z direction. The first layer 76A has a refractive index of n1 while the second layer 76B has a refractive index of n2 (n1≠n2). The layers can be composed of any materials as long as the relationship between the refractive indexes is satisfied.

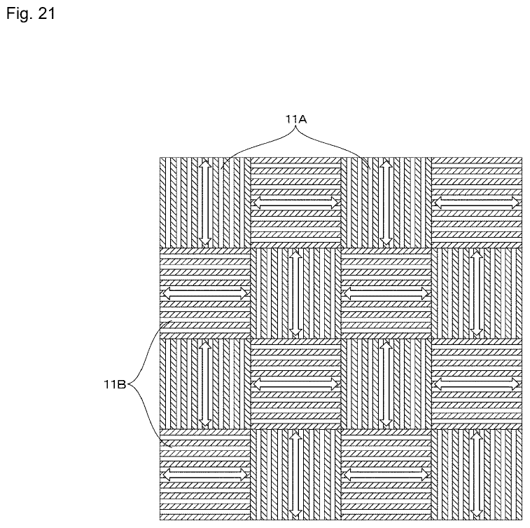

As shown schematically in FIG. 21, the arrangement direction of the grating structure GR can be varied appropriately for each of the light-emitting elements 11, allowing one of the light-emitting elements 11 to act as the first light-emitting element 11A and another of the light-emitting elements 11 to act as the second light-emitting element 11B. Specifically, the polarization control unit 76 has the grating structure GR in a first arrangement direction, so that light emitted from the excitation light source layer 61 can be TM polarized light. The polarization control unit 76 has the grating structure GR in a second arrangement direction orthogonal to the first arrangement direction, so that light emitted from the excitation light source layer 61 can be TE polarized light. In other words, without varying the stress distributions of the light-emitting elements 11 (light-emitting elements 11 having the same structure) as in the first embodiment, the first light L1 and the second light L2 can be easily formed with different polarization characteristics by using the polarization control unit 76. Furthermore, by using the Q-switch laser, the performance of the light-emitting element 11 can be improved and the cost can be reduced.

An operation example of the light-emitting element 11 in FIG. 19 will be described below. Current is injected into the active layer 67 via the electrode of the excitation light source layer 61, so that laser oscillation with the first wavelength 11 occurs in the first resonator 71 and the excitation light L11 is generated. When the excitation light L11 enters the solid-state laser medium 62, the solid-state laser medium 62 is excited to generate the emitted light L12 with the second wavelength a2. Since the saturable absorber 63 is bonded to the solid-state laser medium 62 and the polarization control unit 76, the emitted light L12 from the solid-state laser medium 62 is absorbed by the saturable absorber 18 and light is not emitted by the fourth reflective layer R4 on the emission surface of the saturable absorber 63 in the initial step in which laser oscillation occurs in the first resonator 71. This does not cause Q-switch laser oscillation.

Thereafter, the solid-state laser medium 62 is sufficiently saturated and the output of the emitted light L12 increases and exceeds a certain threshold value. At this point, the light absorptance of the saturable absorber 63 decreases rapidly and the natural emitted light L12 generated in the solid-state laser medium 62 can be transmitted through the saturable absorber 63. Thus, the second resonator 72 resonates the emitted light L12 between the second reflective layer R2 and the fourth reflective layer R4, and a laser beam is output from the fourth reflective layer R4. When the emitted light L12 is resonated through the second resonator 72, the emitted light L12 is subjected to polarization control by passing through the grating structure GR. When Q-switch laser oscillation occurs in the second resonator 72, the emitted light L12 having been subjected to polarization control is emitted as a laser beam (first light L1 or second light L2) from the fourth reflective layer R4 to a space on the right side of FIG. 13. Thus, the laser beam is output as a Q-switch laser pulse.

The subsequent operations are similar to those of the foregoing embodiments. For example, the FOV is extended by the diffraction element 13 acting on the second light L2 emitted from the second light-emitting element 11B configured as a Q-switch laser. Moreover, the diffraction element 13 does not act on the first light L1 emitted from the first light-emitting element 11A configured as a Q-switch laser, so that spot irradiation is obtained with a high light density.

Furthermore, a nonlinear optical crystal can be disposed in the second resonator 72. The wavelength of a laser pulse after waveform conversion can be changed according to the kind of nonlinear optical crystal. Examples of wavelength conversion material include nonlinear optical crystals such as LiNbO3, BBO, LBO, CLBO, BiBO, KTP, and SLT. Furthermore, a phase matching material similar to these materials may be used as a wavelength conversion material. However, any kind of waveform conversion material may be used. The second wavelength λ2 can be converted to another wavelength by using the wavelength conversion material.

As an example of the polarization control unit 76, a photonic crystal polarization element using a photonic crystal or a polarization element using a metasurface may be used. In other words, the fine structure of the polarization control unit 76 may be a photonic crystal or a metasurface structure in addition to the grating structure.

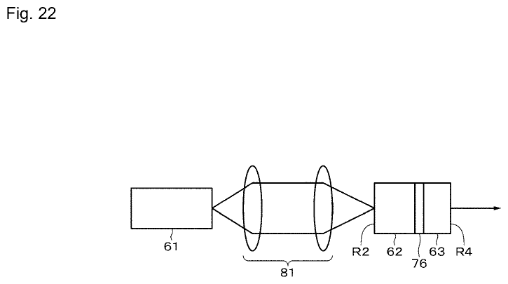

The light-emitting element 11 according to the present embodiment may be configured as illustrated in FIG. 22. As illustrated in FIG. 22, the solid-state laser medium 62 and the saturable absorber 63 are bonded to each other with the polarization control unit 76 interposed therebetween. As described above, the second reflective layer R2 is a highly reflective layer, and the fourth reflective layer R4 is a partially reflective layer. The excitation light source layer 61 is not bonded to the solid-state laser medium 62 and the saturable absorber 63, and a microlens array 81, which is an example of a condenser lens unit, is disposed between the excitation light source layer 61 and the solid-state laser medium 62. In the present embodiment, a light beam emitted from the excitation light source layer 61 is condensed onto the solid-state laser medium 62 through the microlens array 81. A light beam (first light L1 or second light L2) having undergone Q-switch oscillation is emitted in a plurality of regions arranged in the solid-state laser medium 62.

### Modification Example

Although embodiments of the present disclosure have been described above in detail, the content of the present disclosure is not limited to the above-described embodiments, and various modifications based on the technical spirit of the present disclosure can be made.

In the foregoing embodiments, the first light L1 is described as TM polarized light and the second light L2 is described as TE polarized light, but the opposite may also be true. Moreover, the first light L1 and the second light L2 may have polarization characteristics such as polarization directions not orthogonal to each other, as long as the polarization characteristics are different from each other. Although the embodiments described switching of two FOVs, three or more FOVs may be switched.

The configurations, methods, steps, shapes, materials, and numerical values and the like of the foregoing embodiments can be changed as appropriate without departing from the gist of the present disclosure. The configuration examples described in the embodiments can be combined or replaced with one another.

The effects described in the present specification are merely examples and are not intended as limiting, and other effects may be obtained.

The present technique can also be configured as follows:

(1) A lighting device including:
a light-emitting unit including a first light-emitting element that emits first light and a second light-emitting element that emits second light,
wherein a projection range of the first light and a projection range of the second light are changed by causing the light-emitting unit and an optical member disposed on the optical path of the first light and the second light to act differently on the first light and the second light.

(2)

The lighting device according to (1), wherein the projection range of the first light and the projection range of the second light are changed by causing the optical member not to act on the first light but to refract or diffract only the second light.

(3)

The lighting device according to (1) or (2), wherein the first light and the second light have different polarization characteristics.

(4)

The lighting device according to (3), wherein the first light and the second light have polarization characteristics orthogonal to each other.

(5)

The lighting device according to (1), wherein the optical member is a polarization diffraction element.

(6)

The lighting device according to (1), wherein the optical member is a liquid crystal element.

(7)

The lighting device according to (1), wherein the optical member is a polarization metamaterial.

(8)

The lighting device according to any one of (1) to (7), wherein the lighting device includes a plurality of the first light-emitting elements and a plurality of the second light-emitting elements.

(9)

The lighting device according to any one of (1) to (8), wherein the lighting device includes the optical member.

(10)

The lighting device according to any one of (1) to (9), wherein the first light-emitting element and the second light-emitting element are surface-emitting semiconductor lasers.

(11)

The lighting device according to any one of (1) to (9), wherein the first light-emitting element and the second light-emitting element each have a configuration including an excitation light source layer, a laser medium, and a saturable absorber.

(12)

The lighting device according to (11), wherein the first light-emitting element and the second light-emitting element each have a configuration in which the excitation light source layer, the laser medium, and the saturable absorber are stacked.

(13)

A ranging device including: the lighting device according to any one of (1) to (12);
a control unit that controls the lighting device;
a light receiving unit that receives reflected light from an object; and
a ranging unit that calculates a measured distance from image data obtained by the light receiving unit.

(14)

An onboard device including the ranging device according to (13).

### Application Examples

A technique according to the present technique is not limited to the foregoing application example and can be applied to various products. For example, the technique according to the present disclosure may be implemented as an apparatus mounted on any kind of mobile body such as an automobile, an electric vehicle, a hybrid electric vehicle, a motorcycle, a bicycle, a personal mobility, an airplane, a drone, a ship, a robot, a construction machine, or an agricultural machine (tractor).

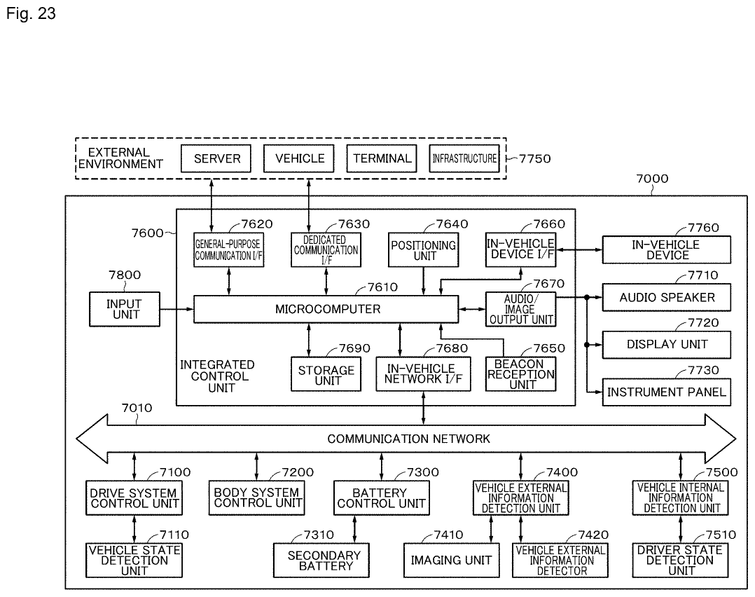

FIG. 23 is a block diagram illustrating a schematic configuration example of a vehicle control system 7000 that is an example of a mobile control system to which a technique according to the present technique is applicable. The vehicle control system 7000 includes a plurality of electronic control units connected via a communication network 7010. In the example illustrated in FIG. 23, the vehicle control system 7000 includes a drive system control unit 7100, a body system control unit 7200, a battery control unit 7300, a vehicle external information detection unit 7400, a vehicle internal information detection unit 7500, and an integrated control unit 7600. The communication network 7010 connecting the plurality of control units may be, for example, an in-vehicle communication network compliant with any standards such as CAN (Controller Area Network), LIN (Local Interconnect Network), LAN (Local Area Network), and FlexRay (registered trademark).

Each control unit includes a microcomputer that performs arithmetic processing according to various programs, a storage unit that stores programs executed by the microcomputer or parameters or the like used for various arithmetic operations, and a drive circuit that drives various devices to be controlled. Each control unit includes a network I/F for performing communication with another control unit via the communication network 7010, and a communication I/F for performing communication with devices or sensors inside or outside of the vehicle through wired communication or wireless communication. In FIG. 23, a microcomputer 7610, a general-purpose communication I/F 7620, a dedicated communication I/F 7630, a positioning unit 7640, a beacon reception unit 7650, an in-vehicle device I/F 7660, an audio/image output unit 7670, an in-vehicle network I/F 7680, and a storage unit 7690 are shown as functional configurations of the integrated control unit 7600. Other control units also include a microcomputer, a communication I/F, and a storage unit.

The drive system control unit 7100 controls the operations of devices related to the drive system of the vehicle according to various programs. For example, the drive system control unit 7100 functions as a control device for a driving force generation device for generating a vehicle driving force of an internal combustion engine or a drive motor, a driving force transmission mechanism for transmitting the driving force to wheels, a steering mechanism for adjusting a steering angle of the vehicle, and a braking device that generates a braking force of the vehicle. The drive system control unit 7100 may have a function as a control device, for example, an ABS (Antilock Brake System) or ESC (Electronic Stability Control).

A vehicle state detection unit 7110 is connected to the drive system control unit 7100. The vehicle state detection unit 7110 includes, for example, at least one of a gyro sensor that detects an angular velocity of an axial rotation motion of a vehicle body, an acceleration sensor that detects an acceleration of a vehicle, and a sensor that detects, for example, an operation amount of an acceleration pedal, an operation amount of a brake pedal, a steering angle of a steering wheel, an engine speed, or a wheel rotation speed or the like. The drive system control unit 7100 performs arithmetic processing using a signal input from the vehicle state detection unit 7110 and controls an internal combustion engine, a driving motor, an electric power steering device, or a brake device or the like.

The body system control unit 7200 controls operations of various devices equipped in the vehicle body in accordance with various programs. For example, the body system control unit 7200 functions as a control device of a keyless entry system, a smart key system, a power window device, or various lamps such as a head lamp, a back lamp, a brake lamp, a turn indicator, and a fog lamp. In this case, radio waves emitted from a portable device in place of a key or signals of various switches can be input to the body system control unit 7200. The body system control unit 7200 receives inputs of radio waves or signals and controls a door lock device, a power window device, and a lamp of the vehicle.

The battery control unit 7300 controls a secondary battery 7310, which is a power supply source of the drive motor, according to various programs. For example, information such as a battery temperature, a battery output voltage, or a remaining capacity of a battery is input from a battery device including the secondary battery 7310 to the battery control unit 7300. The battery control unit 7300 performs arithmetic processing using such a signal and performs temperature adjustment control of the secondary battery 7310 or control of a cooling device equipped in the battery device.

The vehicle external information detection unit 7400 detects information outside of the vehicle in which the vehicle control system 7000 is mounted. For example, at least one of an imaging unit 7410 and a vehicle external information detector 7420 is connected to the vehicle external information detection unit 7400. The imaging unit 7410 includes at least one of a ToF (Time Of Flight) camera, a stereo camera, a monocular camera, an infrared camera, and other cameras. The vehicle external information detector 7420 includes at least one of, for example, an environmental sensor that detects the present weather or atmospheric phenomena and a surrounding information detection sensor that detects other vehicles, obstacles, or pedestrians around a vehicle where the vehicle control system 7000 is mounted.

The environmental sensor may be, for example, at least one of a raindrop sensor that detects rainy weather, a fog sensor that detects fog, a sunshine sensor that detects the degree of sunshine, and a snow sensor that detects snowfall. The surrounding information detection sensor may be at least one of an ultrasonic sensor, a radar device, and a LIDAR (Light Detection and Ranging, Laser Imaging Detection and Ranging) device. The imaging unit 7410 and the vehicle external information detector 7420 may be included as independent sensors or devices or may be included as a device in which a plurality of sensors or devices are integrated.

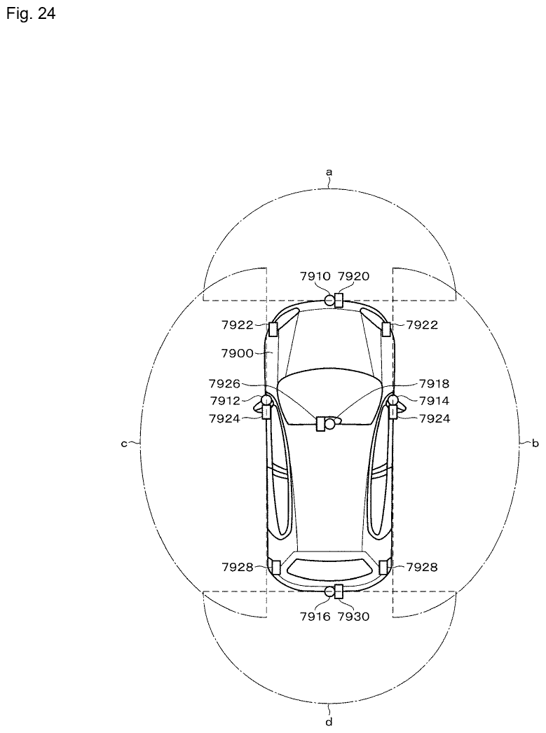

FIG. 24 illustrates an example of installation positions of the imaging unit 7410 and the vehicle external information detector 7420. Imaging units 7910, 7912, 7914, 7916, and 7918 are provided, for example, at least one of a front nose, side mirrors, a rear bumper, a back door, and an upper part of a windshield in a vehicle cabin of a vehicle 7900. The imaging unit 7910 provided on the front nose and the imaging unit 7918 provided in the upper portion of the windshield inside of the vehicle mainly acquire images on the front side of the vehicle 7900. The imaging units 7912 and 7914 provided on the side mirrors mainly acquire images on the lateral sides of the vehicle 7900. The imaging unit 7916 provided on the rear bumper or the backdoor mainly acquires images on the rear side of the vehicle 7900. The imaging unit 7918 provided in the upper portion of the windshield inside of the vehicle is mainly used to detect vehicles ahead, pedestrians, obstacles, traffic signals, traffic signs, or lanes and the like.

FIG. 24 shows an example of the imaging ranges of the imaging units 7910, 7912, 7914, and 7916. An imaging range a indicates an imaging range of the imaging unit 7910 provided on the front nose, imaging ranges b and c indicate imaging ranges of the imaging units 7912 and 7914 provided on the side mirrors, and an imaging range d indicates an imaging range of the imaging unit 7916 provided on the rear bumper or the back door. For example, a bird's-eye view image of the vehicle 7900 can be obtained by superimposing image data captured by the imaging units 7910, 7912, 7914, and 7916.

Vehicle external information detectors 7920, 7922, 7924, 7926, 7928, and 7930 provided on the front, rear, sides, corners, and an upper part of the windshield in the vehicle 7900 may be, for example, ultrasonic sensors or radar devices. The vehicle external information detectors 7920, 7926, and 7930 provided on the front nose, rear bumper, back door, and upper part of the windshield in the vehicle 7900 may be, for example, LIDAR devices. These vehicle external information detectors 7920 to 7930 are mainly used for detecting vehicles ahead, pedestrians, or obstacles and the like.

The description will be continued with reference to FIG. 23 again. The vehicle external information detection unit 7400 causes the imaging unit 7410 to capture an image of the outside of the vehicle and receives captured image data. Furthermore, the vehicle external information detection unit 7400 receives detection information from the connected vehicle external information detector 7420. When the vehicle external information detector 7420 is an ultrasonic sensor, a radar device, or an LIDAR device, the vehicle external information detection unit 7400 transmits ultrasonic waves or electromagnetic waves and the like and receives information on received reflected waves. The vehicle external information detection unit 7400 may perform object detection processing or distance detection processing for a person, a vehicle, an obstacle, a sign, or a character on a road surface on the basis of the received information. The vehicle external information detection unit 7400 may perform environment recognition processing for recognizing rainfall, fog, or a road surface situation and the like on the basis of the received information. The vehicle external information detection unit 7400 may calculate a distance to an object outside of the vehicle on the basis of the received information.

Furthermore, the vehicle external information detection unit 7400 may perform image recognition processing or distance detection processing for recognizing a person, a vehicle, an obstacle, a sign, or a character on a road surface on the basis of the received image data. The vehicle external information detection unit 7400 may perform processing such as distortion correction or alignment on the received image data, and combine image data captured by the different imaging units 7410 to generate a bird's-eye view image or a panoramic image. The vehicle external information detection unit 7400 may perform viewpoint conversion processing using the image data captured by the different imaging units 7410.

The vehicle internal information detection unit 7500 detects information inside of the vehicle. For example, a driver state detection unit 7510 that detects a driver's state is connected to the vehicle internal information detection unit 7500. The driver state detection unit 7510 may include a camera that captures an image of a driver, a biological sensor that detects biological information of the driver, or a microphone that collects sound in the vehicle. The biological sensor is provided on, for example, a seat surface or a steering wheel, and detects biological information about a passenger on a seat or a driver holding the steering wheel. The vehicle internal information detection unit 7500 may calculate a degree of fatigue or a degree of concentration of the driver on the basis of detection information input from the driver state detection unit 7510, and may determine whether the driver is asleep. The vehicle internal information detection unit 7500 may perform processing such as noise canceling processing on the collected audio signal.

The integrated control unit 7600 controls overall operations in the vehicle control system 7000 according to various programs. An input unit 7800 is connected to the integrated control unit 7600. The input unit 7800 is implemented by a device that can be operated for an input by a passenger. The device is, for example, a touch panel, a button, a microphone, a switch, or a lever. Data obtained by recognizing voice input through a microphone may be input to the integrated control unit 7600. The input unit 7800 may be, for example, a remote control device using infrared rays or other radio waves, or may be an externally connected device such as a mobile phone or a PDA (Personal Digital Assistant) that supports an operation on the vehicle control system 7000. The input unit 7800 may be, for example, a camera. In this case, the passenger can input information by gesture. Alternatively, data obtained by detecting a motion of a wearable device worn by a passenger may be input. Furthermore, the input unit 7800 may include, for example, an input control circuit that generates an input signal on the basis of information input by the passenger or the like using the input unit 7800 and outputs the input signal to the integrated control unit 7600. The passenger or the like inputs various types of data to the vehicle control system 7000 or provides an instruction about a processing operation by operating the input unit 7800.

The storage unit 7690 may include a ROM (Read Only Memory) that stores various programs to be executed by a microcomputer, and a RAM (Random Access Memory) that stores various parameters, calculation results, or sensor values or the like. The storage unit 7690 may be implemented by, for example, a magnetic storage device such as an HDD (Hard Disc Drive), a semiconductor storage device, an optical storage device, or a magneto-optical storage device.

The general-purpose communication I/F 7620 is a general-purpose communication I/F that mediates communication with various devices present in an external environment 7750. The general-purpose communication I/F 7620 may have, implemented therein, a cellular communication protocol such as GSM (Global System of Mobile communications) (registered trademark), WiMAX (registered trademark), LTE (Long Term Evolution) (registered trademark), or LTE-A (LTE-Advanced), or other wireless communication protocols such as wireless LAN (also referred to as Wi-Fi (registered trademark)) or Bluetooth (registered trademark). The general-purpose communication I/F 7620 may be connected to, for example, a device (for example, an application server or a control server) present on an external network (for example, the Internet, a cloud network, or a business-specific network) via a base station or an access point. The general-purpose communication I/F 7620 may be connected to terminals (for example, the terminals of the driver, pedestrians, or shops, or MTC (Machine-Type Communication) terminals) near the vehicle by using, for example, the P2P (Peer To Peer) technique.

The dedicated communication I/F 7630 is a communication I/F supporting a communication protocol formulated for the purpose of use in a vehicle. The dedicated communication I/F 7630 may implement, for example, a standard protocol such as WAVE (Wireless Access in Vehicle Environment) that is a combination of IEEE 802.11p of a lower layer and IEEE1609 of an upper layer, DSRC (Dedicated Short Range Communications), or a cellular communication protocol. The dedicated communication I/F 7630 typically performs V2X communications as a concept including one or more of vehicle-to-vehicle communications, vehicle-to-infrastructure communications, vehicle-to-home communications, and vehicle-to-pedestrian communications.

The positioning unit 7640 receives, for example, a GNSS signal from a GNSS (Global Navigation Satellite System) satellite (for example, a GPS signal from a GPS (Global Positioning System) satellite), executes positioning, and generates position information including the latitude, longitude, and altitude of the vehicle. The positioning unit 7640 may specify a current position by exchanging signals with a wireless access point, or may acquire position information from a terminal such as a mobile phone, PHS, or smartphone having a positioning function.

The beacon reception unit 7650 receives radio waves or electromagnetic waves transmitted from a radio station or the like installed on a road, and acquires information such as a current position, traffic jam, no throughfare, or required time. The function of the beacon reception unit 7650 may be included in the above-described dedicated communication I/F 7630.

The in-vehicle device I/F 7660 is a communication interface that mediates connections between the microcomputer 7610 and various in-vehicle devices 7760 present in the vehicle. The in-vehicle device I/F 7660 may establish a wireless connection using wireless communication protocols such as a wireless LAN, Bluetooth (registered trademark), NFC (Near Field Communication), and WUSB (Wireless USB). Furthermore, the in-vehicle device I/F 7660 may establish a wired connection of, for example, a USB (Universal Serial Bus), HDMI (registered trademark) (High-Definition Multimedia Interface), or MHL (Mobile High-definition Link) via a connection terminal (and a cable if necessary), which is not illustrated. The in-vehicle device 7760 may include, for example, at least one of a mobile device or a wearable device of the passenger and an information device carried in or attached to the vehicle. Furthermore, the in-vehicle device 7760 may include a navigation device that searches for a route to any destination. The in-vehicle device I/F 7660 exchanges control signals or data signals with the in-vehicle devices 7760.

The in-vehicle network I/F 7680 is an interface that mediates communications between the microcomputer 7610 and the communication network 7010. The in-vehicle network I/F 7680 transmits and receives signals or the like in conformity with a predetermined protocol supported by the communication network 7010.

The microcomputer 7610 of the integrated control unit 7600 controls the vehicle control system 7000 in accordance with various programs based on information acquired through at least one of the general-purpose communication I/F 7620, the dedicated communication I/F 7630, the positioning unit 7640, the beacon reception unit 7650, the in-vehicle device I/F 7660, and the in-vehicle network I/F 7680. For example, the microcomputer 7610 may calculate control target values for a driving force generation device, a steering mechanism, or a braking device on the basis of acquired information on the inside and outside of the vehicle, and output control commands to the drive system control unit 7100. For example, the microcomputer 7610 may perform cooperative control for the purpose of implementing the functions of ADAS (Advanced Driver Assistance System), the functions including vehicle collision avoidance or impact mitigation, follow-up traveling based on an inter-vehicle distance, vehicle speed maintenance driving, a vehicle collision warning, and a vehicle lane departure warning. The microcomputer 7610 may perform coordinated control for automated driving in which a vehicle travels autonomously regardless of an operation of a driver, by controlling, for example, a driving force generation device, a steering mechanism, or a braking device on the basis of acquired surrounding information on the vehicle.

The microcomputer 7610 may generate three-dimensional distance information between the vehicle and objects such as surrounding structures or persons on the basis of information acquired via at least one of the general-purpose communication I/F 7620, the dedicated communication I/F 7630, the positioning unit 7640, the beacon reception unit 7650, the in-vehicle device I/F 7660, and the in-vehicle network I/F 7680 and may generate local map information including surrounding information of a present position of the vehicle. The microcomputer 7610 may predict a danger such as collision of the vehicle, approach of a pedestrian, or entry into a closed road on the basis of the acquired information and may generate a warning signal. The warning signal may be, for example, a signal for generating a warning sound or turning on a warning lamp.

The audio/image output unit 7670 transmits output signals of at least one of sound and images to an output device capable of visually or audibly notifying a passenger of the vehicle or the outside of the vehicle of information. In the example of FIG. 23, an audio speaker 7710, a display unit 7720, and an instrument panel 7730 are illustrated as output devices. For example, the display unit 7720 may include at least one of an on-board display and a head-up display. The display unit 7720 may have an AR (Augmented Reality) display function. The output device may be other devices such as a headphone, a wearable device such as a glasses-type display worn by a passenger, a projector, or a lamp. When the output device is a display device, the display device visually displays results obtained through various processes performed by the microcomputer 7610 or information received from another control unit in various formats such as text, images, tables, and graphs. When the output device is a sound output device, the sound output device converts an audio signal including reproduced sound data or acoustic data into an analog signal and outputs the analog signal auditorily.

In the example illustrated in FIG. 23, at least two control units connected via the communication network 7010 may be integrated as one control unit. Alternatively, each control unit may be composed of a plurality of control units. Furthermore, the vehicle control system 7000 may include another control unit (not illustrated). In the foregoing description, some or all of the functions of any one of the control units may be included in another control unit. In other words, predetermined arithmetic processing may be performed by any one of the control units as long as information is transmitted and received via the communication network 7010. Similarly, a sensor or device connected to any one of the control units may be connected to another control unit, and a plurality of control units may mutually transmit or receive detection information via the communication network 7010.

In the foregoing vehicle control system 7000, the lighting device of the present technique is applicable to, for example, the vehicle external information detector.

### REFERENCE SIGNS LIST

1 Ranging device
2, 2A Light-emitting unit
11 Light-emitting element
11A First light-emitting element
11B Second light-emitting element
13 Diffraction element
27 Organic liquid crystal element
33 Metamaterial
54 Polarization diffraction element
76 Polarization control unit
L1 First light
L2 Second light

1. Alighting device comprising a light-emitting unit including a first light-emitting element that emits first light and a second light-emitting element that emits second light,
wherein a projection range of the first light and a projection range of the second light are changed by causing the light-emitting unit and an optical member disposed on the optical path of the first light and the second light to act differently on the first light and the second light.

2. The lighting device according to claim 1, wherein the projection range of the first light and the projection range of the second light are changed by causing the optical member not to act on the first light but to refract or diffract only the second light.

3. The lighting device according to claim 1, wherein the first light and the second light have different polarization characteristics.

4. The lighting device according to claim 3, wherein the first light and the second light have polarization characteristics orthogonal to each other.

5. The lighting device according to claim 1, wherein the optical member is a polarization diffraction element.

6. The lighting device according to claim 1, wherein the optical member is a liquid crystal element.

7. The lighting device according to claim 1, wherein the optical member is a polarization metamaterial.

8. The lighting device according to claim 1, wherein the lighting device includes a plurality of the first light-emitting elements and a plurality of the second light-emitting elements.

9. The lighting device according to claim 1, wherein the lighting device includes the optical member.

10. The lighting device according to claim 1, wherein the first light-emitting element and the second light-emitting element are surface-emitting semiconductor lasers.

11. The lighting device according to claim 1, wherein the first light-emitting element and the second light-emitting element each have a configuration including an excitation light source layer, a laser medium, and a saturable absorber.

12. The lighting device according to claim 11, wherein the first light-emitting element and the second light-emitting element each have a configuration in which the excitation light source layer, the laser medium, and the saturable absorber are stacked.

13. A ranging device comprising: the lighting device according to claim 1;
a control unit that controls the lighting device;
a light receiving unit that receives reflected light from an object; and
a ranging unit that calculates a measured distance from image data obtained by the light receiving unit.

14. An onboard device comprising the ranging device according to claim 13.
